(19) United States
(12) Patent Application Publication
(10) Pub. No.: US 2023/0387204 A1
(43) Pub. Date: Nov. 30, 2023

(54) EPITAXIAL SOURCE/DRAIN STRUCTURE WITH HIGH DOPANT CONCENTRATION

(71) Applicant: Taiwan Semiconductor Manufacturing Company, Ltd., Hsinchu (TW)

(72) Inventors: Chih Sheng Huang, New Taipei City (TW); Ming-Hua Yu, Hsinchu (TW); Yee-Chia Yeo, Hsinchu (TW)

(21) Appl. No.: 17/824,915

(22) Filed: May 26, 2022

(51) Int. Cl. H01L 29/08; H01L 29/04; H01L 29/78; H01L 29/66

(52) U.S. Cl. CPC H01L 29/0847; H01L 29/045; H01L 29/785; H01L 29/7848; H01L 29/66795; H01L 21/02532

(57) ABSTRACT

A semiconductor device includes a plurality of nanostructures, a gate dielectric layer disposed on each nanostructure of the plurality of nanostructures, a gate electrode disposed on the gate dielectric layer and on the plurality of nanostructures, and a source/drain region adjacent to the nanostructures. The source/drain region includes an epitaxial structure including a polygonal-shaped upper portion and a column-like lower portion, wherein the polygonal-shaped upper portion has multiple facets, and each of the facets characterized by a (111) crystallographic orientation. The polygonal-shaped upper portion includes corner regions adjacent an intersection of two facets with a (111) crystallographic orientation and an epitaxial body region in contact with the corner regions. The corner regions are characterized by a first dopant concentration and the epitaxial body region is characterized by a second dopant concentration, and the first dopant concentration is higher than the second dopant concentration.

### BACKGROUND

Technological advances in semiconductor integrated circuit (IC) materials and design have produced generations of ICs with smaller and more complex circuits. Functional density has increased while geometry size has decreased. Besides providing improved circuit speed and larger integrated circuits, this scaling down process also provides benefits by increasing production efficiency and lowering costs.

The advancement of IC technology has led to transistor structures such as fin-type field effect transistor (FinFET) and gate-all-around (GAA) devices. The continuing scaling has also led to ever shrinking device features that are characterized by higher resistance. Therefore, improved device structures and methods are highly desirable.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a three-dimensional (3D) view diagram illustrating an intermediate structure of a semiconductor FinFET device, in accordance with some embodiments.

FIG. 2 is a three-dimensional (3D) view diagram illustrating another intermediate structure of a semiconductor FinFET device, in accordance with some embodiments.

FIGS. 3A and 3B are cross-sectional view diagrams illustrating yet another intermediate structure of a semiconductor FinFET device, in accordance with some embodiments.

FIGS. 4A-4F are cross-sectional view diagrams illustrating a process for forming an intermediate structure of a semiconductor FinFET device, in accordance with some embodiments.

FIG. 5A is a three-dimensional (3D) view diagram illustrating an epitaxial source/drain (S/D) region in an intermediate structure of a semiconductor FinFET device, in accordance with some embodiments.

FIG. 5B is a cross-sectional view diagram illustrating an epitaxial source/drain (S/D) region in an intermediate structure of a semiconductor FinFET device, in accordance with some embodiments.

FIG. 6 is another three-dimensional (3D) view diagram illustrating an epitaxial source/drain (S/D) region in an intermediate structure of a semiconductor FinFET device, in accordance with some embodiments.

FIG. 7 is a plot illustrating a relationship between a boron cluster area and boron concentration in an epitaxial source/drain (S/D) region in an intermediate structure of a semiconductor FinFET device, in accordance with some embodiments.

FIG. 8 is another three-dimensional (3D) view diagram illustrating an epitaxial source/drain (S/D) region in an intermediate structure of a semiconductor FinFET device, in accordance with some embodiments.

FIG. 9 is yet another three-dimensional (3D) view diagram illustrating an epitaxial source/drain (S/D) region in an intermediate structure of a semiconductor FinFET device, in accordance with some embodiments.

FIG. 10 is a flowchart illustrating a method for forming an epitaxial source/drain (S/D) region in an intermediate structure of a semiconductor FinFET device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Advanced IC technologies often include advanced transistor device structures such as fin-type field effect transistor (FinFET) and gate-all-around (GAA) devices. These advanced transistor device structures often are formed with epitaxial source/drain regions. Epitaxially grown materials are implemented to increase device speed and reduce device power consumption. For example, source/drain terminals of transistor devices formed of doped epitaxial materials can provide benefits, such as enhanced carrier mobility and improved device performance. Epitaxial source/drain terminals can be formed by epitaxially disposing crystalline material on a substrate. As the semiconductor industry continues to scale down the dimensions of semiconductor devices, circuit complexity has increased at all device levels. For example, beyond the 5 nm technology node or the 3 nm technology node, increased source/drain resistance can limit circuit speed. However, it has become increasingly challenging to form epitaxial material with high dopant concentration in finFET or GAA devices for forming source/drain terminals, without forming defects in the deposited material. Defects in the crystalline lattice in the source/drain structures can impact device performance and reduce device yield.

In order to reduce source/drain resistance and boost device performance, it is desirable to raise the active dopant concentration in the source/drain region. However, in embodiments of the invention, it has been observed that, in p-type devices, an oversupply of the boron dopants can cause boron clusters to form in the p-type epitaxial silicon-germanium (SiGe) lattice. Serious boron clusters can retard p-type epitaxial growth in the (100) crystalline orientation, especially at the cross-section of two (111) plane regions, which can cause incomplete crystallization and lower growth of the p-type source/drain region.

In some embodiments, a method is provided for forming the epitaxial source/drain region, in which the local boron clusters serve as extra boron dopant sources in post-epitaxial thermal treatment due to dissolution of the boron clusters, and thus increase the boron concentration of the epitaxial layers. The epitaxial source/drain structure and process described herein provide various benefits that can improve device performance, reliability, and yield. The benefits can include, but are not limited to, reduced source/drain resistance, reduced source/drain metal contact resistance, and reduced epitaxial layer loss during the contact etch process, among other things. The embodiments described herein use finFETs as examples and can also be applied to other semiconductor structures, such as GAAFETs and planar FETs. In addition, the embodiments described herein can be used in various technology nodes.

In some embodiments, a semiconductor device includes a plurality of nanostructures, a gate dielectric layer disposed on each nanostructure of the plurality of nanostructures, a gate electrode disposed on the gate dielectric layer and on the plurality of nanostructures, and a source/drain region adjacent to the nanostructures. The source/drain region includes an epitaxial structure with a polygonal-shaped upper portion and a column-like lower portion, wherein the polygonal-shaped upper portion has multiple facets, and each of the facets is characterized by a (111) crystallographic orientation. The polygonal-shaped upper portion includes corner regions adjacent an intersection of two facets with a (111) crystallographic orientation and an epitaxial body region in contact with the corner regions. The corner regions are characterized by a first dopant concentration and the epitaxial body region is characterized by a second dopant concentration, and the first dopant concentration is higher than the second dopant concentration. The corner regions function as additional boron sources to supply additional boron dopants which diffuse to the epitaxial body region to raise the dopant concentration.

Further, in some embodiments, a method is provided, which includes forming a plurality of nanostructures on a substrate, forming spacers adjacent to the nanostructures, and etching the substrate to form recesses between the nanostructures. The method also includes forming an epitaxial structure between two nanostructures and doping the epitaxial structure with boron. The epitaxial structure is formed with a polygonal-shaped upper portion and a column-like lower portion. The polygonal-shaped upper portion has multiple facets characterized by a (111) crystallographic orientation. The polygonal-shaped upper portion includes corner regions adjacent an intersection of two facets that have a (111) crystallographic orientation and an epitaxial body region in contact with the corner regions. The corner regions are characterized by a first boron concentration and the epitaxial body region is characterized by a second boron concentration, and the first dopant concentration is higher than the second dopant concentration. In some embodiments, the method also includes further thermal processes to allow the boron dopants to diffuse from the corner regions to the epitaxial body region.

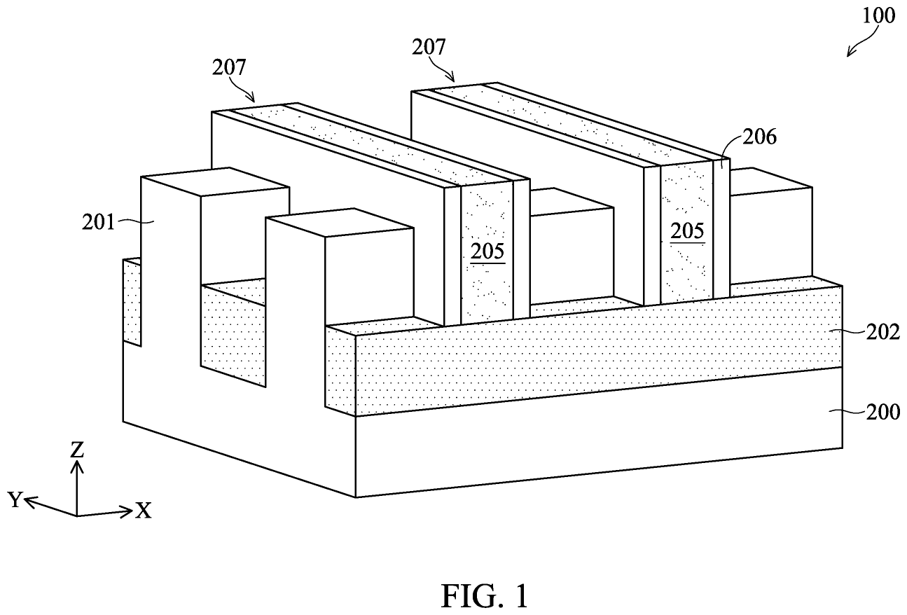

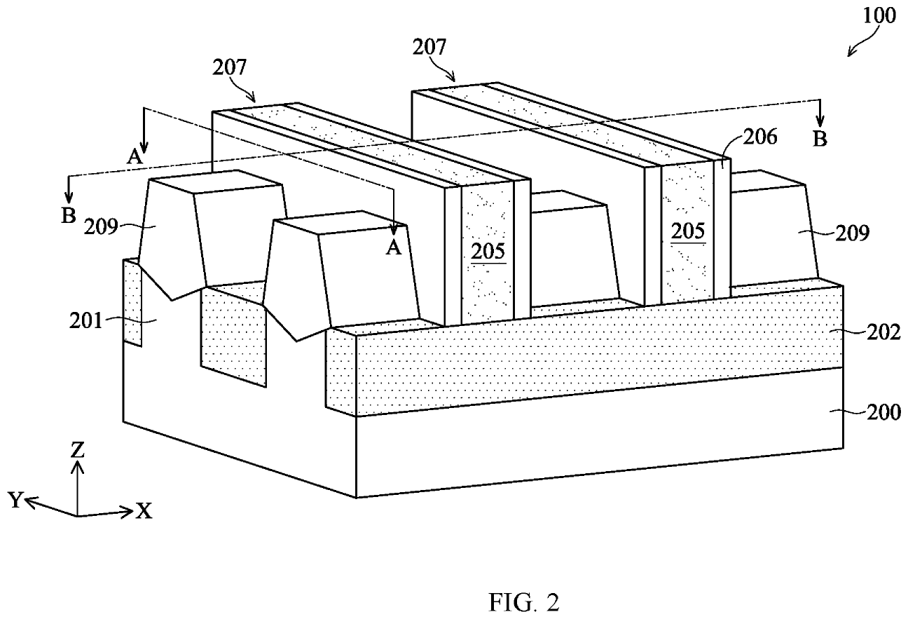

FIG. 1 and FIG. 2 are three-dimensional (3D) view diagrams illustrating intermediate structures of a semiconductor FinFET device, in accordance with some embodiments. Referring to FIG. 1, semiconductor structure 100 includes a substrate 200 having a plurality of fins 201. The substrate 200 is a semiconductor substrate, such as a bulk semiconductor substrate, a semiconductor-on-insulator (SOI) substrate, or the like, which may be doped (e.g., with a p-type or an n-type dopant) or undoped. The substrate 200 may be a semiconductor wafer, such as a silicon wafer. Other substrates, such as a multi-layered or gradient substrate may also be used. In some embodiments, the material of the substrate 200 may include silicon; germanium; a compound semiconductor including silicon carbide (SiC), gallium arsenic (GaAs), gallium phosphide (GaP), indium phosphide (InP), indium arsenide (InAs), and/or indium antimonide (InSb); an alloy semiconductor including SiGe, GaAsP, AlInAs, AlGaAs, GalnAs, GaInP, and/or GaInAsP; or combinations thereof.

Depending on the design, the substrate 200 may be a P-type substrate, an N-type substrate or a combination thereof and may have doped regions therein. The substrate 200 may be configured for an N-type FinFET device or a P-type FinFET device. In some embodiments, the substrate 200 for an N-type FinFET device may include Si, SiP, SiC, SiPC, InP, GaAs, AlAs, InAs, InAlAs, InGaAs or combinations thereof. The substrate 200 for a P-type FinFET device may include Si, SiGe, SiGeB, Ge, InSb, GaSb, InGaSb or combinations thereof.

The fins 201 protrude from a top surface of a body portion of the substrate 200. The substrate 200 has an isolation structure 202 formed thereon. The isolation structure 202 covers lower portions of the fins 201 and exposes upper portions of the fins 201. In some embodiments, the isolation structure 202 may include a shallow trench isolation (STI) structure, a cut poly structure, or a combination thereof. The isolation structure 202 includes an insulation material, which may be an oxide, such as silicon oxide, a nitride such as silicon nitride, the like, or combinations thereof.

A plurality of gate structures 207 are formed on the substrate 200 and across the plurality of fins 201. In some embodiments, the gate structures 207 are dummy gate structures and may be replaced by metallic gate structures through a gate replacement process in subsequent steps. In some embodiments, the gate structure 207 may include a dummy gate electrode 205 and spacers 206 on sidewalls of the dummy gate electrode 205.

The dummy gate electrodes 205 may be formed by the following processes: in some embodiments, a dummy layer is formed on the substrate 200 covering the fins 201, and the isolation structure 202, and the dummy layer is then patterned by photolithography and etching processes. In some embodiments, the dummy layer may be a conductive material and may be selected from a group including polycrystalline-silicon (polysilicon), poly-crystalline silicon-germanium (poly-SiGe), metallic nitrides, metallic silicides, metallic oxides, and metals. In one embodiment, amorphous silicon is deposited and recrystallized to create polysilicon. In some embodiments, the dummy layer may include a silicon-containing material such as polysilicon, amorphous silicon, or combinations thereof. The dummy layer may be formed by a deposition process such as physical vapor deposition (PVD), chemical vapor deposition (CVD), or other suitable deposition process. In some embodiments, the fins 201 extend in the direction X, and the dummy gate electrodes 207 extend in the direction Y different from (e.g., perpendicular to) the direction X.

In some embodiments, a gate dielectric layer and/or an interfacial layer (not shown) may be disposed at least between the dummy electrode 205 and the fins 201 of the substrate 200. The gate dielectric layer and/or the interfacial layer may include silicon oxide, silicon nitride, silicon oxynitride, or the like, or combinations thereof, and may be formed by thermal oxidation process, suitable deposition process such as CVD, ALD, or other suitable process known in the art, or combinations thereof.

Spacers 206 are respectively formed on sidewalls of the dummy gate electrodes 205. In some embodiments, the spacer 206 includes SiO2, SiN, SiCN, SiOCN, SiC, SiOC, SiON, or the like, or combinations thereof.

Referring to FIG. 1 and FIG. 2, in some embodiments, after the dummy gate structures 207 are formed, S/D regions 209 are formed on opposite sides of the gate structures 207, and the portions of the fins 201 covered by the gate structures 207 and laterally sandwiched between the S/D regions 209 serve as the channel regions. The S/D regions 209 may be located in and/or on the fins 201 of the substrate 200. In some embodiments, the S/D regions 209 are strained layers (epitaxial layers) formed by an epitaxial growing process such as a selective epitaxial growing process. In some embodiments, a recessing process is performed on the fins 201, and recesses are formed in the fins 201 on sides of the gate structure 207, and the strained layers are formed by selectively growing epitaxy layers from the fins 201 exposed in the recesses. In some embodiments, the strained layers include silicon germanium (SiGe), SiGeB, Ge, InSb, GaSb, InGaSb or combinations thereof for a P-type FinFET device. In alternative embodiments, the strained layers include silicon carbon (SiC), silicon phosphate (SiP), SiCP, InP, GaAs, AlAs, InAs, InAlAs, InGaAs or a SiC/SiP multi-layer structure, or combinations thereof for an N-type FinFET device. In some embodiments, the strained layers may be optionally implanted with an N-type dopant or a P-type dopant as needed.

In some embodiments, the fin 201 is recessed to have a top surface lower than the top surface of the isolation structure 202, and a portion of the S/D region 209 may be embedded in the isolation structure 202. For example, the S/D region 209 includes an embedded portion and a protruding portion on the embedded portion. The embedded portion is embedded in the isolation structure 202, and the protruding portion protrudes from the top surface of the isolation structure 202. However, the disclosure is not limited thereto. In alternative embodiments, the fin 201 may be recessed with a top surface higher than the top surface of the isolation structure 202, and the S/D region 209 may not be embedded in isolation structure 202, and may completely protrude above the top surface of the isolation structure 202.

It is noted that the shape of the S/D region 209 shown in the figures is merely for illustration, and the disclosure is not limited thereto. The S/D region 209 may have any suitable shape according to product design and requirement.

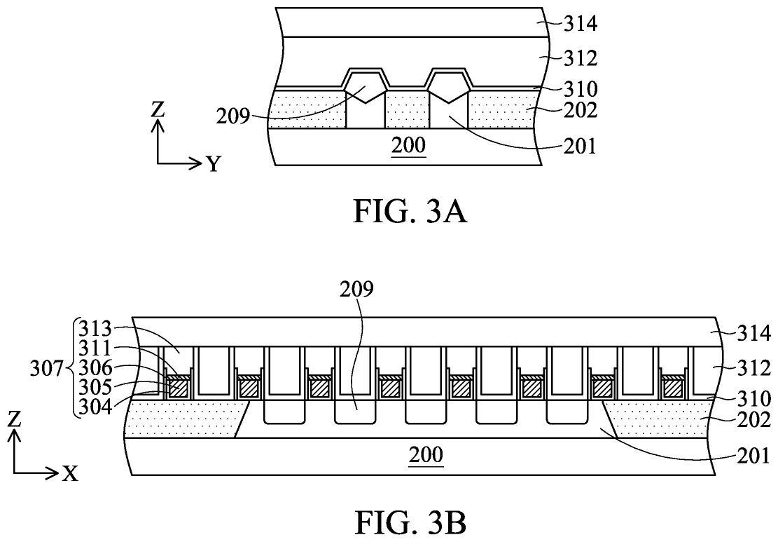

FIGS. 3A and 3B are schematic cross-sectional views illustrating intermediate stages for forming a semiconductor FinFET device, following the process of forming S/D regions 209 shown in FIG. 2 in accordance with some embodiments. FIG. 3A illustrates the subsequent processes performed on the semiconductor device 200 taken along the A-A line of FIG. 2, while FIG. 3B illustrates the subsequent processes performed on the semiconductor device 200 taken along the B-B line of FIG. 2.

Referring to FIGS. 2, 3A, and 3B, in some embodiments, after the S/D regions 209 are formed on sides of the gate structure 207 in FIG. 2, an etching stop layer 310 and a dielectric layer 312 are formed laterally aside the gate structure 207, and the gate structure 207 is replaced by a gate structure 307 in FIG. 3B, and a dielectric layer 314 is formed on the gate structure 307 and the dielectric layer 312.

In some embodiments, the etching stop layer 310 may also be referred to as a contact etch stop layer (CESL), and is disposed between the substrate 200 (e.g., the S/D regions 209 and the isolation structure 202 of the substrate 200) and the dielectric layer 312 and between the gate structure 307 and the dielectric layer 312. In some embodiments, the etching stop layer 310 includes SiN, SiC, SiOC, SiON, SiCN, SiOCN, or the like, or combinations thereof. The etching stop layer 310 may be formed by CVD, plasma-enhanced CVD (PECVD), flowable CVD (FCVD), ALD or the like.

The dielectric layer 312 is formed laterally aside the gate structure 307, and may have a top surface substantially coplanar with the top surface of the gate structure 307. The dielectric layer 312 includes a material different from that of the etching stop layer 310. In some embodiments, the dielectric layer 312 may also be referred to as an interlayer dielectric layer (ILD), such as ILD0. In some embodiments, the dielectric layer 312 includes silicon oxide, carbon-containing oxide such as silicon oxycarbide (SiOC), silicate glass, tetraethylorthosilicate (TEOS) oxide, un-doped silicate glass, or doped silicon oxide such as borophosphosilicate glass (BPSG), fluorine-doped silica glass (FSG), phosphosilicate glass (PSG), boron doped silicon glass (BSG), combinations thereof and/or other suitable dielectric materials. In some embodiments, the dielectric layer 312 may include low-k dielectric material with a dielectric constant lower than 4, or extreme low-k (ELK) dielectric material with a dielectric constant lower than 2.5. In some embodiments, the low-k material includes a polymer-based material, such as benzocyclobutene (BCB), FLARE®, or SILK®; or a silicon dioxide-based material, such as hydrogen silsesquioxane (HSQ) or SiOF. The dielectric layer 312 may be a single layer structure or a multi-layer structure. The dielectric layer 312 may be formed by CVD, PECVD, FCVD, spin coating, or the like.

In some embodiments, the etching stop layer 310 and the dielectric layer 312 may be formed by the following processes: after the S/D regions 209 are formed as shown in FIG. 2, an etching stop material layer and a dielectric material layer are formed over the substrate 200 to cover the isolation structure 202, the S/D regions 209, and the gate structure 207; thereafter, a planarization process is performed to remove excess portions of the etching stop material layer and the dielectric material layer over the top surfaces of the gate structures 207, so as to expose the gate structure 207, and the etching stop layer 310 and the dielectric layer 312 are thus formed laterally aside the gate structures 207.

In some embodiments, after the formation of the etching stop layer 310 and the dielectric layer 312, the gate structure 207 is replaced by the gate structure 307 through a gate replacement process. In some embodiments, the gate structure 307 is a metallic gate structure and may include a gate dielectric layer 304, a gate electrode 305, a protection layer 311, spacers 306 and a helmet 313.

In some embodiments, the gate electrode 305 is a metallic gate electrode, and may include a work function metal layer and a metal filling layer on the work function metal layer. The work functional metal layer is configured to tune a work function of its corresponding FinFET to achieve a desired threshold voltage Vt. The work function metal layer may be an N-type work function metal layer or a P-type work function metal layer. In some embodiments, the P-type work function metal layer includes a metal with a sufficiently large effective work function and may include one or more of the following: TiN, WN, TaN, conductive metal oxide, and/or a suitable material, or combinations thereof. In alternative embodiments, the N-type work function metal layer includes a metal with sufficiently low effective work function and may comprise one or more of the following: tantalum (Ta), titanium aluminide (TiAl), titanium aluminum nitride (TiAlN), tantalum carbide (TaC), tantalum carbide nitride (TaCN), tantalum silicon nitride (TaSiN), titanium silicon nitride (TiSiN), other suitable metals, suitable conductive metal oxide, or combinations thereof. The metal filling layer may include copper, aluminum, tungsten, cobalt (Co), or any other suitable metallic material, or the like or combinations thereof. In some embodiments, the metal gate electrode 305 may further include a liner layer, an interface layer, a seed layer, an adhesion layer, a barrier layer, combinations thereof or the like.

In some embodiments, the gate dielectric layer 304 surrounds the sidewalls and bottom surface of the gate electrode 305. In alternative embodiments, the gate dielectric layer 304 may be disposed on a bottom surface of the gate electrode 305 and between the gate electrode 305 and the substrate 200, without being disposed on sidewalls of the gate electrode 305. In some embodiments, the gate dielectric layer 304 may include silicon oxide, silicon nitride, silicon oxynitride, high-k dielectric materials, or combinations thereof. The high-k dielectric material may have a dielectric constant such as greater than about 4, or greater than about 7 or 10. In some embodiments, the high-k material includes metal oxide, such as ZrO2, Gd2O3, HfO2, BaTiO3, Al2O3, LaO2, TiO2, Ta2O5, Y2O3, STO, BTO, BaZrO, HfZrO, HfLaO, HfTaO, HfTiO, combinations thereof, or a suitable material. In alternative embodiments, the gate dielectric layer 104 may optionally include a silicate such as HfSiO, LaSiO, AlSiO, combinations thereof, or a suitable material.

In some embodiments, a protection layer 311 is optionally formed on the gate electrode 305. In some embodiments, the protection layer 311 includes substantially fluorine-free tungsten (FFW) film. The FFW film may be formed by atomic layer deposition (ALD) or CVD using one or more non-fluorine-based W precursors such as, but not limited to, tungsten pentachloride (WCl5), tungsten hexachloride (WCl6), or a combination thereof. In some embodiments, the protection layer 311 is formed to cover the gate electrode 305 and may further extend to cover the top surface of the gate dielectric layer 304 and contact the spacers 306. In alternative embodiments, the protection layer 311 merely covers the top surface of the metal gate electrodes 305. The sidewalls of the protection layer 311 may be aligned with the sidewalls of the gate electrode 305 or the sidewalls of the gate dielectric layer 304, and the disclosure is not limited thereto.

The spacers 306 are disposed on sidewalls of the gate electrode 305, and portions of the gate dielectric layer 304 may be laterally sandwiched between the gate electrode 305 and the spacers 306. The spacers 306 may have a height less than the spacers 206 in FIG. 2, but the disclosure is not limited thereto. In some embodiments, the top surfaces of the spacers 306 are higher than the top surface of the protection layer 311 on the gate electrode 305.

In some embodiments, the helmet 313 is formed over the gate electrode 305 to cover the protection layer 311 and the spacers 306. The helmet 313 includes a dielectric material, such as nitride (e.g., silicon nitride), oxide (e.g., silicon oxide), silicon oxycarbide, or the like, or combinations thereof, and the disclosure is not limited thereto.

In some embodiments, the formation of the gate structure 307 includes a gate replacement process. For example, the dummy gate electrode 205 and/or the dummy dielectric layer/interfacial layer of the dummy gate structure 207 in FIG. 2 are removed, and a gate trench defined by the spacers 206 is formed. A gate dielectric material layer and gate electrode materials are then formed within the gate trench. Thereafter, recessing processes are performed to remove portions of the gate dielectric material layer and the gate electrode materials, and the gate dielectric layer 304 and gate electrode 305 are thus formed. In some embodiments, portions of the spacers 206 may also be removed to form the spacers 306 with a smaller height. The protection layer 311 is formed on the gate electrode 305, and the helmet 313 is then formed to cover the protection layer 311 and the spacers 306. In some embodiments, the top surface of the helmet 313 is substantially coplanar with the top surface of the dielectric layer 312.

Thereafter, the dielectric layer 314 is formed on the gate structure 307 and the dielectric layer 312. The material of dielectric layer 314 may be selected from the same candidate materials as the dielectric layer 312, and may be formed by a similar process of the dielectric layer 312. The dielectric layer 314 may also be referred to as an interlayer dielectric layer (ILD), such as ILD1. In some embodiments, both of the dielectric layer 312 and the dielectric layer 314 include silicon oxide formed by FCVD process. In some embodiments, an etching stop layer (not shown) may further be formed on the gate structure 307 and dielectric layer 312 before forming the dielectric layer 314.

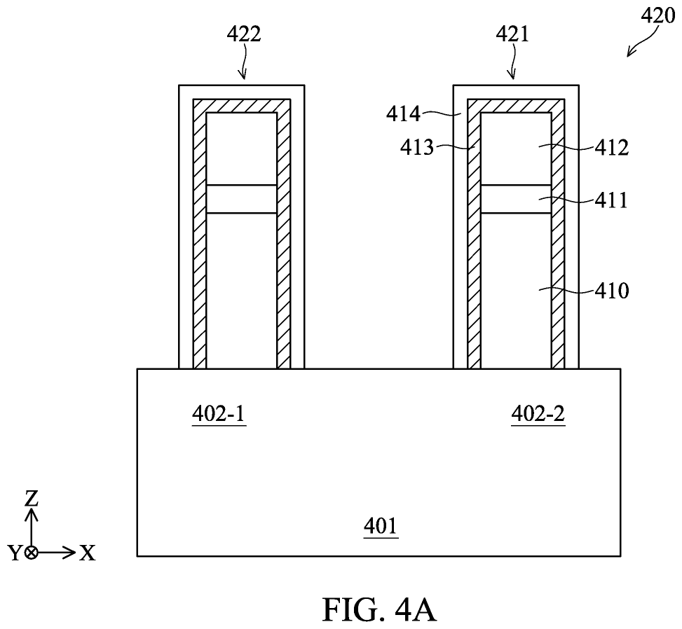

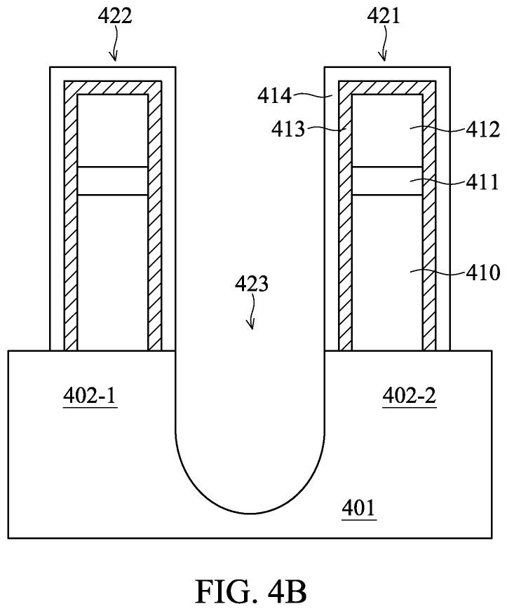

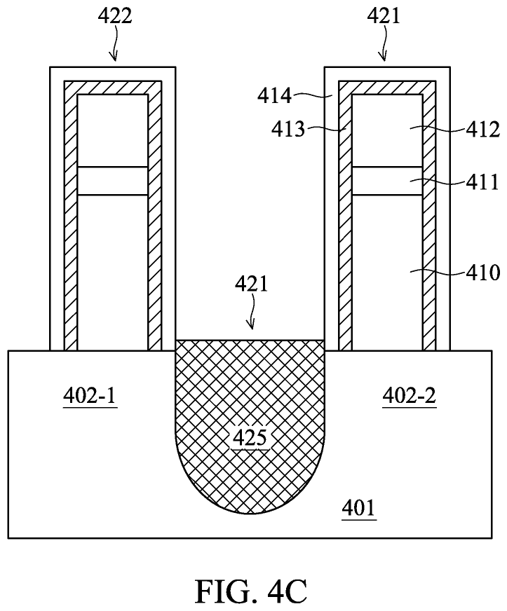

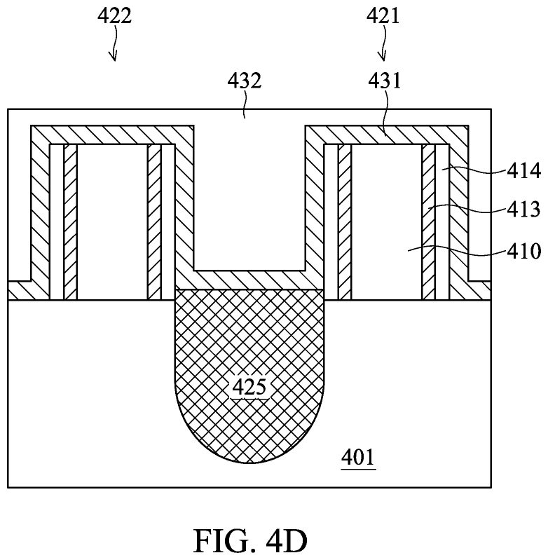

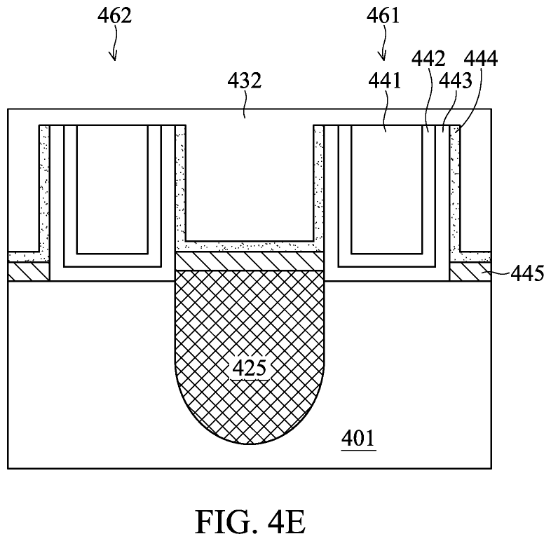

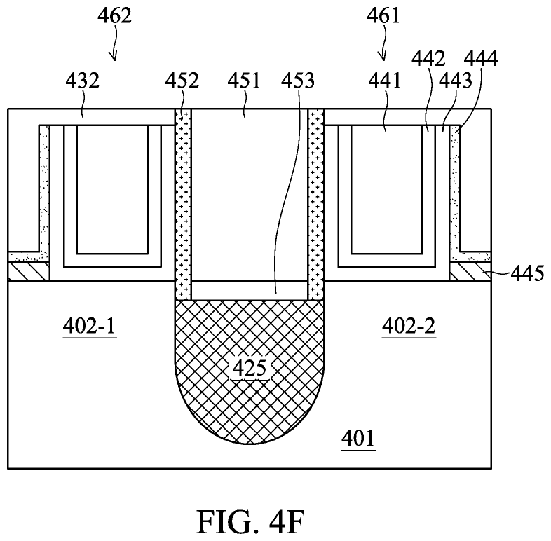

FIGS. 4A-4F are cross-sectional view diagrams illustrating a process for forming intermediate device structures a semiconductor FinFET device, in accordance with some embodiments. The FinFET device illustrated in FIGS. 4A-4F is similar to those described above in connection to FIGS. 1, 2, 3A, and 3B, and references are made to the processes and materials described above. The cross-sectional views of device structures in FIGS. 4A-4F are taken across the X-Z plane, similar to the cross-sectional views across the X-Z plane and along cut line BB of device structures in FIG. 2 and the cross-sectional view across the X-Z plane of device structures in FIG. 3B.

FIG. 4A shows a first intermediate device structure 420 including two polysilicon dummy gate structures, 421 and 422, on a substrate 401. In some embodiments, substrate 401 is a semiconductor substrate, which can include nanostructures. In FIG. 4A, semiconductor substrate 401 includes a plurality of nanostructures, 402-1 and 402-2. In some embodiments, the nanostructures are semiconductor fin structures. FIG. 4A shows two polysilicon gates 410, overlaid by a first dielectric layer 411 and a hard mask 412. In some embodiments, the first dielectric layer 411 is a silicon oxide and hard mask 412 is silicon nitride or silicon oxycarbonitride (SiOCN). After an etching process using the hard mask as a masking layer, the two polysilicon dummy gate structures are covered with dielectric layers 413 and 414. In some embodiments, dielectric layer 414 is silicon nitride SiN, and dielectric layer 413 is SiOCN. However, the structures can also be formed using the materials and processes for forming similar device structures as described above in connection to FIGS. 1, 2, 3A, and 3B.

In FIG. 4B, a recess 423 is formed between the two polysilicon dummy gate structures, 421 and 422. The recess is formed using a patterning process including masking and etching using similar masking and etching processes described above in connection to FIGS. 1, 2, 3A, and 3B.

In FIG. 4C, an epitaxial structure 425 is formed as the source/drain of the device, similar to the S/D regions 209 in FIGS. 1, 2, 3A, and 3B. In some embodiments, the S/D regions 209 are strained layers (epitaxial layers) formed by an epitaxial growing process such as a selective epitaxial growing process. In some embodiments, a recessing process is performed on the fins 201, and recesses are formed in the fins 402-1 and 402-2 on the sides of the dummy gate structures 421 and 422, and the strained layers are formed by selectively growing epitaxy layers from the fins exposed in the recesses. In some embodiments, the strained layers include silicon germanium (SiGe), SiGeB, Ge, InSb, GaSb, InGaSb or combinations thereof for a P-type FinFET device. In alternative embodiments, the strained layers include silicon carbon (SiC), silicon phosphate (SiP), SiCP, InP, GaAs, AlAs, InAs, InAlAs, InGaAs or a SiC/SiP multi-layer structure, or combinations thereof for an N-type FinFET device. In some embodiments, the strained layers may be optionally implanted with an N-type dopant or a P-type dopant as needed.

In some embodiments, the forming of the epitaxial structure 425 includes using a cyclic-deposition-etch (CDE) process to form a silicon germanium (SiGe) structure. The cyclic-etch-dep (CDE) process refers to a repeated deposition/partial etch process. In some embodiments, forming the epitaxial structure includes using a cyclic-etch-dep (CDE) process with a flow rate ratio of etching gas to deposition gas (E/D ratio) in a range between 0.20 to 0.40. In some embodiments, the E/D ratio is defined as the ratio of etching gas flow rate and the deposition gas flow rate, which is a parameter that determines the net reaction direction of epitaxy. In some embodiments, the higher E/D ratio is adjusted for more boron cluster formation. In contrast, the conventional processes are known to use an E/D ratio of below 0.20 or below 0.15. In some embodiments, the etching gas includes one or more of HCl and Cl2, and the deposition gas includes one or more of silane (SiH4) and diclorosilane (SiH2Cl2), etc. In some embodiments, the flow rate of HCl or Cl2 is between 35-1000 sccm, the flow rate of SiH4 is about 10-150 sccm, and the flow rate of dichlosilane (DCS) is about 10-200 sccm. In some embodiments, the flow rate of germanium (Ge) or GeH4 is about 50-1000 sccm. In some embodiments, the gases are further diluted.

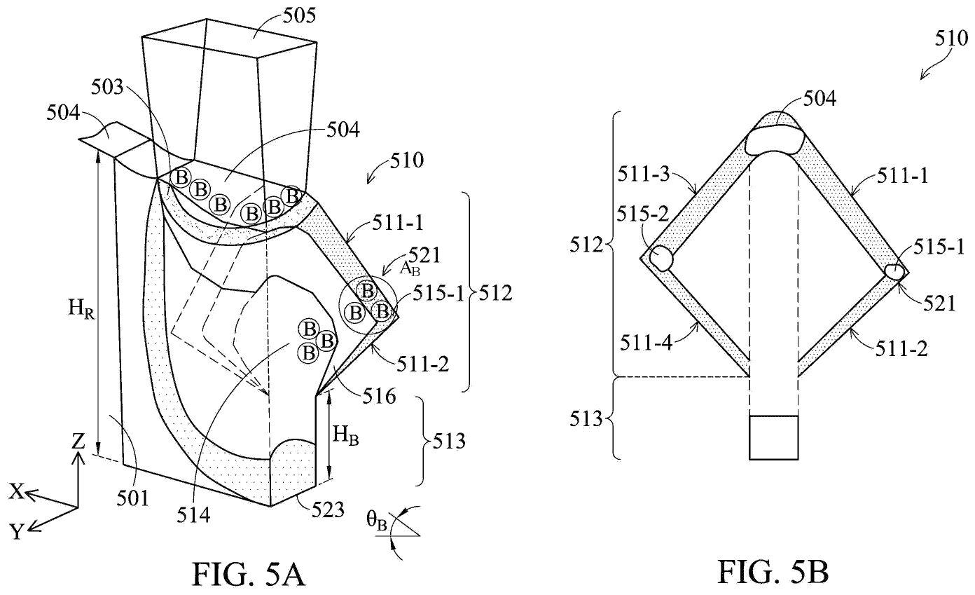

In some embodiments, the forming of the epitaxial structure includes in-situ doping. For p-type dopants, the in-situ doping uses p-type doping precursors, such as diborane (B2H6), boron tricloride (BCl3), or boron trifluoride (BF3), or other p-type doping precursors. In some embodiments, the in-situ doping process is carried out at a temperature of 500-700° C., a pressure of 10-300 torr, and with a gas flow setting for B2H6 and BCl3 of about 20-300 sccm. Further detail of the properties of the epitaxial structure 425 is described below with reference to FIGS. 5-10.

In FIG. 4D, the dielectric layer 411 and hard mask layer 412 are removed, and a contact etch stop layer (CESL) 431 is deposited. Subsequently, an interlayer dielectric layer (ILD0) 432 is deposited on the CESL layer. The removal of the hard mask layer and the deposition of the CESL and ILD0 are performed using removal and deposition processes described above in connection to FIGS. 1, 2, 3A, and 3B.

In FIG. 4E, the polysilicon dummy gate structures, 412 and 422, are removed and replaced by metal gate structures 461 and 462. The process of replacing the polysilicon dummy gate and a metal gate described above in connection to FIGS. 3A and 3B can be used in forming metal gate structures 461 and 462 in FIG. 4E. As shown in FIG. 4F, metal gate structure 461 includes a metal gate 441, a barrier layer 442, a gate dielectric layer 443, additional dielectric layers 444 and 445, and interlayer dielectric layer (ILD0) 432. In some embodiments, metal gate 441 is copper, barrier layer 442 is TaN, gate dielectric layer 443 is a high-k (HK) dielectric, and the additional dielectric layers 444 and 445 are silicon nitride (SiN). The interlayer dielectric layer (ILD0) 432 is a dielectric, such as a high-k dielectric. The formation of the metal gate structure 461 and 462 is similar to the process for forming similar structures described above in connection to FIGS. 1, 2, 3A, and 3B.

In FIG. 4F, a metal contact 451 is formed to contact the epitaxial structure 425. A barrier/adhesion layer 453, such as a titanium silicide (TiSi) layer is formed between the metal contact 451 and the epitaxial structure 425. A spacer layer 452 is formed at both sides of the metal contact. The spacer layer 452 is made of dielectric materials, such as silicon oxides and/or silicon nitrides.

As shown in FIG. 4F, a semiconductor substrate 401 includes a plurality of nanostructures, 402-1 and 402-2. In some embodiments, the nanostructures are semiconductor fin structures. Examples of fin structures are described above. A gate dielectric layer 443 is disposed around each nanostructure of the plurality of nanostructures. A metal gate electrode 441 is disposed on the gate dielectric layer 443 and on the plurality of nanostructures, 402-1 and 402-2, etc. An epitaxial source/drain region 425 is disposed adjacent to the nanostructures. Further detail of the source/drain region 425 is described below with reference to FIGS. 5A, 5B, and 6-10.

FIG. 5A is a three-dimensional (3D) view diagram illustrating an epitaxial source/drain (S/D) region in an intermediate structure of a semiconductor FinFET device, in accordance with some embodiments. FIG. 5B is a cross-sectional view diagram illustrating the epitaxial source/drain (S/D) region in the intermediate structure of a semiconductor FinFET device in FIG. 5A along the Y-Z plane, in accordance with some embodiments.

FIG. 5A illustrates a portion of a semiconductor device including a plurality of nanostructures. Examples of the plurality of nanostructures are shown in FIGS. 1-4F, where a semiconductor FinFET device is illustrated. It is understood, however, that the description below also applies to other semiconductor nanostructures, such as gate-all-around devices (GAA). FIGS. 5A and 5B illustrate a semiconductor nanostructure 501, which in this case is a semiconductor fin structure. A source/drain region 510 is disposed adjacent to the nanostructures 501. The source/drain region 510 is characterized by a height HR. In some embodiments, the height of the epitaxial structure HR is 40 nm or more. A silicide layer 503 and contact metal 505 are disposed on the source/drain region 510.

In some embodiments, the source/drain region 510 is an epitaxial structure including a polygonal-shaped upper portion 512 and a column-like lower portion 513. The polygonal-shaped upper portion 512 has multiple facets, e.g., 511-1, 511-2, 511-3, and 511-4, etc. Each of the facets characterized by a (111) crystallographic orientation. The polygonal-shaped upper portion 512 includes corner regions, e.g., 515-1 and 515-2, etc., adjacent an intersection of two facets. For example, corner region 515-1 is adjacent to the intersection of facet 511-1 and 511-2, and corner region 515-2 is adjacent to facets 511-3 and 511-4 having a (111) crystallographic orientation. The polygonal-shaped upper portion 512 also has an epitaxial body region 514 in contact with the corner regions 515-1 and 515-2. The corner regions 515 are characterized by a first dopant concentration and the epitaxial body region 514 is characterized by a second dopant concentration. The first dopant concentration is higher than the second dopant concentration. In some embodiments, the epitaxial structure is doped with boron (B), and boron clusters, such as 521, are formed in the corner regions.

In FIG. 5A, the label HR is the depth of the recess in the fin structure formed by the source/drain etch. In some embodiments, HR is 30-60 nm below the top 504 of the fin 501. The label HB is the height of the point of the fin region, where boron clusters 516 start to accumulate. In some embodiments, HB is 5-20 nm above fin recess bottom 523. The circle labeled A_{B} illustrates the size of the boron cluster formation. In some embodiments, A_{B} is in a range of about 5-100 nm² according to TEM (Transmission Electron Microscope) measurement. In contrast, such boron clusters were not found in conventional devices. The label θ_{B} is the angle where boron clusters formed relative to (100) surface. In some embodiments, θ_{B} is 50-60° relative to the (100) surface. In some embodiments, θ_{B} is 54.7°.

In some embodiments, the corner regions 515 are characterized by a boron concentration above 1.0×10²¹/cm³. In some embodiments, the epitaxial body region 514 is characterized by a boron concentration in a range of between about 1.0×10₂₀/cm³ to 1.0×10²¹/cm³ in the as-deposited epitaxial structure. In some embodiments, the corner regions are characterized by a cross-sectional area in a range of between about 1.0/nm² to about 25.0/nm². In some embodiments, the corner regions 515 are characterized by a cross-sectional area in a range of between about 1.0/nm² to about 2.0/nm² and a boron concentration above 1.0×10²¹/cm³. In some embodiments, the corner regions are characterized by a size in a range of between 5 nm² and 100 nm².

In some embodiments, it is found that excessive boron clusters can retard p-type epitaxial region tip-site (100) growth, especially at the cross-section of two (111) plane regions, which can cause lower height of the epitaxial source/drain region. In some cases, excess boron clusters may impede formation of crystalline structures during the epitaxial process, which can lead to lower crystalline quality.

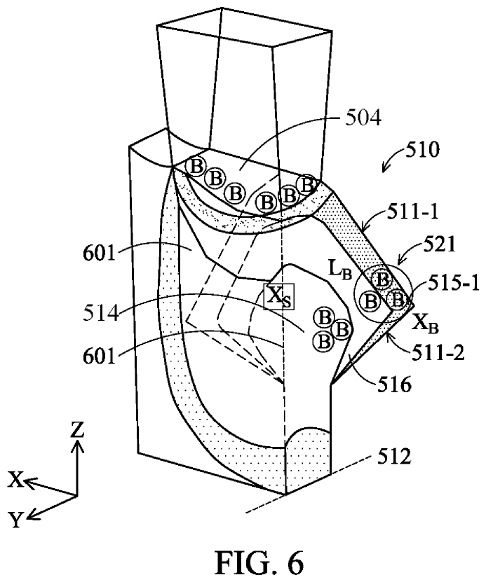

FIG. 6 is another three-dimensional (3D) view diagram illustrating an epitaxial source/drain (S/D) region in an intermediate structure of a semiconductor FinFET device, in accordance with some embodiments. Similar to FIG. 5, FIG. 6 illustrates epitaxial source/drain region 510 including a polygonal-shaped upper portion 512 and a column-like lower portion 513. The polygonal-shaped upper portion 512 includes corner regions, e.g., 515-1 and 515-2, etc., adjacent an intersection of two (111) facets. The polygonal-shaped upper portion 512 also has an epitaxial body region 514 in contact with the corner regions 515-1 and 515-2. As shown in FIGS. 5A and 5B, boron clusters are formed in the corner regions 515. In some embodiments, during thermal treatment associated with fabrication processes after the source/drain formation, the boron dopants diffuse from the corner regions 515 to the body region 514 of the polygonal-shaped upper portion 512. The arrows 601 illustrate the diffusion direction of boron from the corner regions 515 to the epitaxial body region 514.

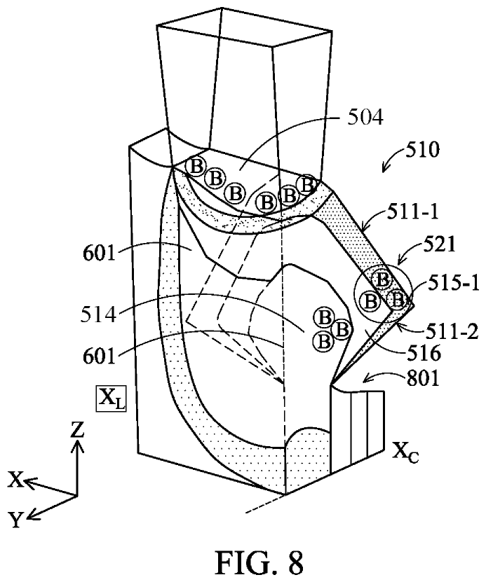

FIG. 6 illustrates that boron clusters can serve as extra boron sources to elevate the boron concentration in the surrounding areas after subsequent thermal treatments. In FIG. 6, the label X_{B} is the boron clusters' formation threshold concentration. In some embodiments, X_{B} is 1.0×10²¹/cm³. In some embodiments, the regions in which the boron concentration is higher than X_{B} is referred to as boron clusters, such as 516 and 521. The label L_{B} is the boron clusters' diffusion length. In some embodiments, L_{B} is approximately 0-5 nm from the edge of the boron clusters. The label X_{S} is the boron concentration in the polygonal-shaped epitaxial region after the B clusters' dissolution following diffusion in subsequent thermal processes. In some embodiments, X_{S} is in a range of between about 1.0×10²⁰/cm³ to about 3.0×10²¹/cm³. The extra boron source can provide this level of boron concentration to surrounding layers within range 0-5 nm, as further explained with reference to FIG. 8.

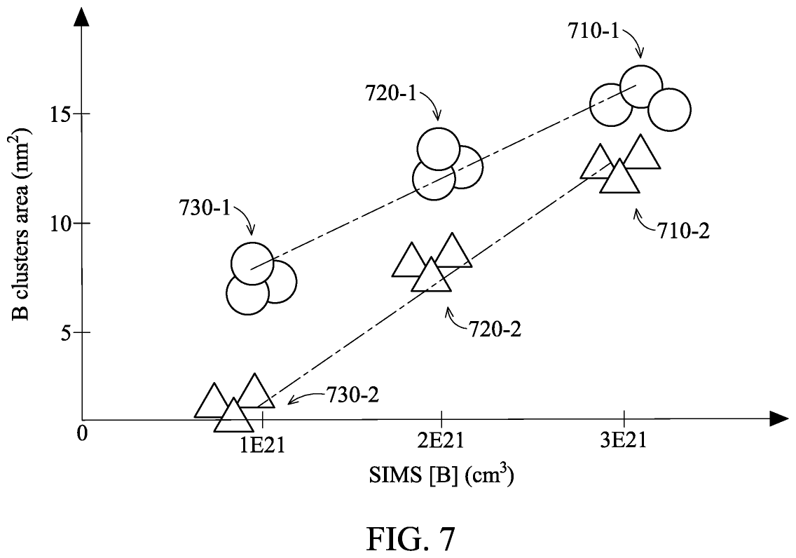

FIG. 7 is a plot illustrating a relationship between boron cluster area and boron concentration in an epitaxial source/drain (S/D) region in an intermediate structure of a semiconductor FinFET device, in accordance with some embodiments. In an experiment, boron cluster area and concentration are measured for three groups of devices, 710, 720, and 730, after the source/drain deposition (As-dep) and at the end of line (EOL). The as-deposited data are shown as 710-1, 720-1, and 730-1, respectively. As shown in FIG. 7, for the first group 710, the as-deposited boron cluster size 710-1 is about 15 nm² and the boron concentration 710-2 is about 3.0×10²¹/cm³. For the second group 720, the as-deposited boron cluster size 720-1 is about 13 nm² and the boron concentration 720-2 is about 2.0×10²¹/cm³. For the third group 730, the as-deposited boron cluster size 730-1 is about 1.0 nm² and the boron concentration 730-2 is about 2.0×10²¹/cm³. It can be seen that dopant diffusion during post-deposit thermal treatment reduces size and dopant concentration of the boron clusters.

FIG. 8 is another three-dimensional (3D) view diagram illustrating an epitaxial source/drain (S/D) region in an intermediate structure of a semiconductor FinFET device, in accordance with some embodiments. Similar to FIGS. 5 and 6, FIG. 8 illustrates epitaxial source/drain region 510 including a polygonal-shaped upper portion 512 and a column-like lower portion 513. The polygonal-shaped upper portion 512 includes corner regions, e.g., 515-1 and 515-2, etc., adjacent an intersection of two (111) facets. The polygonal-shaped upper portion 512 also has an epitaxial body region 514 in contact with the corner regions 515-1 and 515-2. In some cases, the polygonal-shaped upper portion 512 is also referred to as a diamond shape, and the corner region is referred to the tip of the diamond-shaped region.

In some embodiments, carbon-containing sidewall spacers 801 are disposed adjacent to the epitaxial structure. The polygonal-shaped upper portion is disposed above the top of sidewall spacers. More boron clusters are identified as being induced by carbon-containing side wall spacer 801. The label X_{C} is the carbon concentration in the poly spacer. In some embodiments, X_{C} is 0-20% of poly spacer. In some embodiments, higher carbon concentration near the epitaxial growth site induces boron clusters formation due to strong interaction between carbon and boron atoms. In some embodiments, carbon-containing species such as SiOCN are used in the formation of spacers for the polysilicon dummy gates, which provide the carbon in the poly spacers.

In some embodiments, the source/drain epitaxial process includes high in-situ doping of boron that results in higher boron concentration. In some embodiments, the in-situ doping process includes precursors such as B2H6 and BCl3. The higher boron concentration in the epitaxial layer induces more boron clusters formation.

In FIG. 8, the source/drain epitaxial structure is shown as four layers following the sequence of epitaxial growth, layer A, layer B, layer C, and layer D. Layer A is formed first, followed by layer B and layer C. Layer D is the outermost layer. The label XL is the percentage concentration of boron and germanium (Ge) in layer X, where X is A, B, C, or D. In some embodiments, the percentage concentration of Ge is the highest in layer C, lower in layer B, even lower in layer A, and lowest in layer D (C>B>A>D). In some embodiments, the percentage of Ge in each layer is between 0 and 70 atomic percent. Similarly, the percentage concentration of boron is the highest in layer D, lower in layer C, even lower in layer B, and lowest in layer A. In some embodiments, the boron clusters' formation possibility is proportional to the boron concentration in the epitaxial structure.

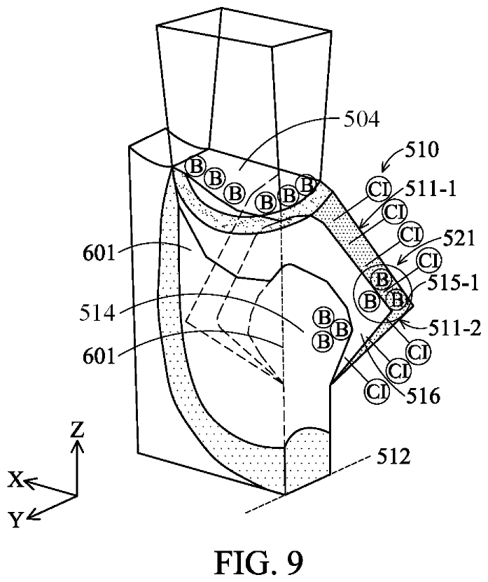

FIG. 9 is yet another three-dimensional (3D) view diagram illustrating an epitaxial source/drain (S/D) region in an intermediate structure of a semiconductor FinFET device, in accordance with some embodiments. Similar to FIGS. 5, 6, and 8, FIG. 9 illustrates epitaxial source/drain region 510 including a polygonal-shaped upper portion 512 and a column-like lower portion 513. The polygonal-shaped upper portion 512 includes corner regions, e.g., 515-1 and 515-2, etc., adjacent an intersection of two (111) facets. The polygonal-shaped upper portion 512 also has an epitaxial body region 514 in contact with the corner regions 515-1 and 515-2.

In some embodiments, forming the epitaxial structure includes using a cyclic-etch-dep (CDE) process with a flow rate ratio of etching gas to deposition gas (E/D ratio) in a range between 0.20 to 0.40. In some embodiments, the E/D ratio is defined as the ratio of etching gas and the deposition gas, which is a parameter that determines the net reaction direction of epitaxy. In some embodiments, the higher E/D ratio is adjusted for more B cluster formation. In contrast, the conventional processes are known to use E/D ratio of below 0.20 or below 0.15. In some embodiments, the etching gas includes one or more of HCl and Cl2, and the deposition gas includes one or more of silane (SiH4) and diclosilane (DCS). In some embodiments, the forming of the epitaxial structure further comprises in-situ doping with a doping gas of one or more of B3H6 and BCl3.

In some embodiments, the higher E/D ratio leads to higher Cl concentration, which induces more B clusters' formation probability in epitaxial process. The strong interaction between B and Cl atoms on (111) surface induces more boron cluster near the corner regions of the polygonal-shaped upper portion 512. FIG. 9 illustrates Cl attached to the surface of the polygonal-shaped upper portion 512 where it induces more boron clusters.

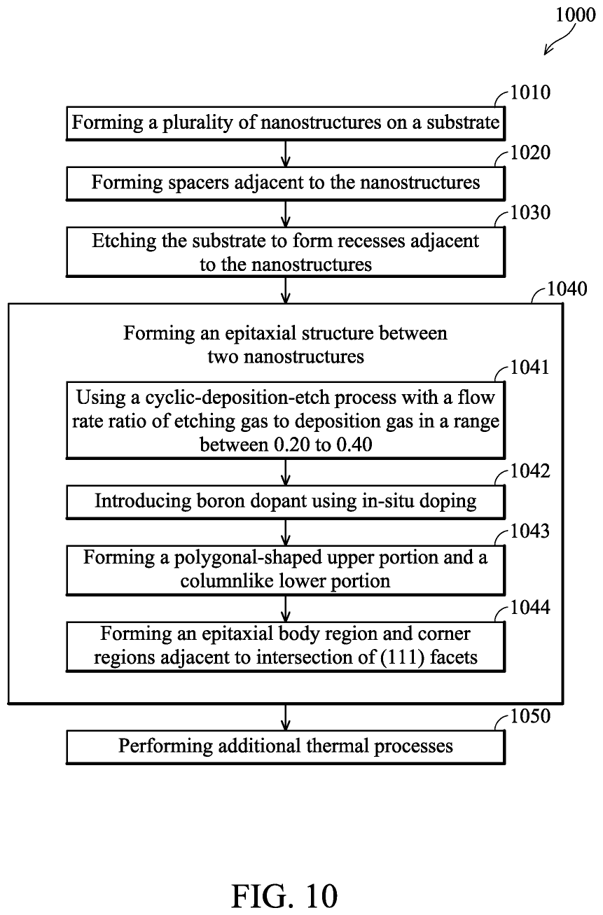

FIG. 10 is a flowchart illustrating a method for forming an epitaxial source/drain (S/D) region in an intermediate structure of a semiconductor FinFET device, in accordance with some embodiments. As shown in FIG. 10, method 1000 is summarized below.
1010 forming a plurality of nanostructures on a substrate;
1020 forming spacers adjacent to the nanostructures;
1030 etching the substrate to form recesses between the nanostructures;
1040 forming an epitaxial structure adjacent to the nanostructures; and
1050 performing further thermal processes.

Various processes in method 1000 are described above in connections to FIGS. 1-9. At 1010, the method 1000 includes forming a plurality of nanostructures on a substrate. At 1020, the method includes forming spacers adjacent to the nanostructures. These processes are described in connection with FIGS. 4A and 4B, with further detail described with reference to FIGS. 1, 2, 3A and 3B.

At 1030, the substrate is etched to form recesses between the nanostructures. This process is described above in connection with FIG. 4B, with further detail in detail described with reference to FIGS. 1, 2, 3A and 3B.

At 1040, the method includes forming an epitaxial structure adjacent to the nanostructures. In process 1040, forming the epitaxial structure further includes:
1041 using a cyclic-etch-dep (CDE) process with a flow rate ratio of etching gas to deposition gas in a range between 0.20 to 0.40;
1042 in-situ boron doping;
1043 forming a polygonal-shaped upper portion and a column-like lower portion;
1044 in the polygonal-shaped upper portion, forming an epitaxial body region and corner regions adjacent to an intersection of two facets having a (111) crystallographic orientation.
   More detail is described above in connection with FIG. 4C, and properties of the epitaxial structure are described above in connection with FIGS. 5-9.

At 1050, the method includes performing further thermal processes. The thermal processes include annealing processes and the processes involved in finishing the integrated circuits following the formation of the source/drain structure. Subsequent processes include contact and interconnect, etc. In these thermal processes, boron dopants are diffused from the boron clusters in the corner regions of the epitaxial structures to the epitaxial body, as described above in connection with FIGS. 6 and 7. As a result, the doping concentration in the source/drain region is increased, and the source/drain resistance and contact resistance are reduced.

In some embodiments, a method is provided for forming the epitaxial source/drain region, in which the local boron clusters can serve as extra boron dopant sources in the post-epitaxial thermal treatment due to dissolution of the boron clusters, and thus increase the boron concentration of each epitaxial layer. The epitaxial source/drain structures and process described herein provide various benefits that can improve device performance, reliability, and yield. The benefits can include, but are not limited to, reduced source/drain resistance, reduced source/drain metal contact resistance, and reduced epitaxial layer loss during the metal-diffusion contact etch, among other things. The embodiments described herein use finFETs as examples and can also be applied to other semiconductor structures, such as GAAFETs and planar FETs. In addition, the embodiments described herein can be used in various technology nodes.

In some embodiments, a semiconductor device includes a plurality of nanostructures, a gate dielectric layer disposed on each nanostructure of the plurality of nanostructures, a gate electrode disposed on the gate dielectric layer and on the plurality of nanostructures, and a source/drain region adjacent to the nanostructures. The source/drain region includes an epitaxial structure including a polygonal-shaped upper portion and a column-like lower portion, wherein the polygonal-shaped upper portion has multiple facets, and each of the facets is characterized by a (111) crystallographic orientation. The polygonal-shaped upper portion includes corner regions adjacent an intersection of two facets with a (111) crystallographic orientation and an epitaxial body region in contact with the corner regions. The corner regions are characterized by a first dopant concentration and the epitaxial body region is characterized by a second dopant concentration, and the first dopant concentration is higher than the second dopant concentration. The corner regions function as additional boron sources to supply additional boron dopants which diffuse to the epitaxial body region to raise the dopant concentration.

In some embodiments, a method is provided for forming the epitaxial source/drain region, in which the local boron clusters serve as extra boron dopant sources in the post-epitaxial thermal treatment due to dissolution of the boron clusters, and thus increase the boron concentration of each epitaxial layer. The epitaxial source/drain structures and process described herein provide various benefits that can improve device performance, reliability, and yield. The benefits can include, but are not limited to, reduced source/drain resistance, reduced source/drain metal contact resistance, and reduced epitaxial layer loss during the metal-diffusion contact etch, among other things. The embodiments described herein use finFETs as examples and can also be applied to other semiconductor structures, such as GAAFETs and planar FETs. In addition, the embodiments described herein can be used in various technology nodes.

The foregoing outlined features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a plurality of nanostructures;
a gate dielectric layer disposed on each nanostructure of the plurality of nanostructures;
a gate electrode disposed on the gate dielectric layer and on the plurality of nanostructures; and
a source/drain region adjacent to the plurality of nanostructures,
wherein the source/drain region comprises an epitaxial structure including a polygonal-shaped upper portion and a column-like lower portion; wherein the polygonal-shaped upper portion has multiple facets, each of the facets characterized by a (111) crystallographic orientation;
wherein the polygonal-shaped upper portion includes corner regions, each of the corner regions adjacent an intersection of two facets with a (111) crystallographic orientation and an epitaxial body region in contact with the corner regions;
wherein the corner regions and are characterized by a first dopant concentration and the epitaxial body region is characterized by a second dopant concentration, and the first dopant concentration is higher than the second dopant concentration.

2. The semiconductor device of claim 1, wherein the epitaxial structure is doped with boron.

3. The semiconductor device of claim 2, wherein the corner regions are characterized by a boron concentration in a range of between about 1.0×10²¹/cm³ to about 3.0×10²¹/cm³;
wherein the corner regions are characterized by a cross-sectional area in a range of between about 1.0/nm² to about 25.0/nm².

4. The semiconductor device of claim 2, wherein the corner regions are characterized by a cross-sectional area above about 1.0/nm² to about 2.0/nm² and a boron concentration in a range of between about 1.0×10²¹/cm³.

5. The semiconductor device of claim 2, wherein the corner regions are characterized by a size in a range of between 5 nm2 and 100 nm2.

6. The semiconductor device of claim 2, further comprising carbon containing sidewall spacers disposed adjacent to the epitaxial structure.

7. A semiconductor device, comprising:
a plurality of nanostructures on a substrate; and
an epitaxial structure adjacent to one of the plurality of nanostructures, wherein the epitaxial structure comprises a polygonal-shaped upper portion and a column-like lower portion; wherein the polygonal-shaped upper portion has multiple facets, each of the facets characterized by a (111) crystallographic orientation;
wherein the polygonal-shaped upper portion comprises:
corner regions, each corner region adjacent an intersection of two of the multiple facets having a (111) crystallographic orientation; and
an epitaxial body region in contact with the corner regions;
wherein the corner regions are characterized by a first dopant concentration and the epitaxial body region is characterized by a second dopant concentration, and the first dopant concentration is higher than the second dopant concentration.

8. The semiconductor device of claim 7, wherein the epitaxial structure is doped with boron (B).

9. The semiconductor device of claim 8, wherein the corner regions are characterized by a boron concentration in a range of between about 1.0×10²¹/cm³ to about 3.0×10²¹/cm³;
wherein the corner regions are characterized by a cross-sectional area in a range of between about 1.0/nm² to about 25.0/nm².

10. The semiconductor device of claim 8, wherein the corner regions are characterized by a cross-sectional area in a range of between about 1.0/nm² to about 2.0/nm² and a boron concentration above about 1.0×10²¹/cm³.

11. The semiconductor device of claim 8, wherein the corner regions are characterized by a size in a range of between 5 nm² and 100 nm².

12. The semiconductor device of claim 8, further comprising carbon-containing sidewall spacers disposed adjacent to the epitaxial structure, and wherein the polygonal-shaped upper portion is above a top of the carbon-containing sidewall spacers.

13. A method, comprising:
forming a plurality of nanostructures on a substrate;
forming spacers adjacent to the nanostructures;
etching the substrate to form recesses between the nanostructures;
forming an epitaxial structure between two of the nanostructures; and
doping the epitaxial structure with boron;
wherein forming the epitaxial structure comprises forming a polygonal-shaped upper portion and a column-like lower portion, wherein:
the polygonal-shaped upper portion has multiple facets characterized by a (111) crystallographic orientation; and
the polygonal-shaped upper portion includes corner regions, each of the corner regions adjacent an intersection of two of the multiple facets having a (111) crystallographic orientation and an epitaxial body region in contact with the corner regions;
wherein the corner regions are characterized by a first boron concentration and the epitaxial body region is characterized by a second boron concentration, and the first dopant concentration is higher than the second dopant concentration,
wherein the method further comprises performing additional thermal processes to allowed boron to diffuse from the corner regions to the epitaxial body region.

14. The method of claim 13, wherein forming the epitaxial structure includes using a cyclic-deposition-etch (CDE) process with a flow rate ratio of etching gas to deposition gas in a range between 0.20 to 0.40.

15. The method of claim 14, wherein the etching gas comprises one or more of HCl and Cl2.

16. The method of claim 14, wherein the deposition gas comprises one or more of silane (SiH4) and diclorosilane (DCS).

17. The method of claim 16, wherein the forming of the epitaxial structure further comprises in-situ doping with a doping gas of one or more of B2H6 and BCl3.

18. The method of claim 13, wherein the corner regions are characterized by a boron concentration in a range of between about 1.0×10²¹/cm³ to about 3.0×10²¹/cm³; wherein the corner regions are characterized by a cross-sectional area in a range of between about 1.0/nm² to about 25.0/nm².

19. The method of claim 13, wherein forming a plurality of spacers comprises forming carbon-containing spacers.

20. The method of claim 13, wherein forming a plurality of nanostructures on a substrate comprises:
forming a plurality of fin structures on the substrate;
forming isolation structures, wherein the fin structures are embedded in the isolation structures;
forming a gate dielectric layer wrapping around each fin structure; and
forming a gate electrode disposed on the gate dielectric layer and on the plurality of nanostructures.
